(19) United States
(12) Patent Application Publication
(10) Pub. No.: US 2004/0080910 A1
(43) Pub. Date: Apr. 29, 2004

(54) Heat dissipating device

(75) Inventor: Seng-Feng Chen, Taipei Hsien (TW)

Correspondence Address: MARGER JOHNSON & McCOLLOM, P.C., 1030 S.W. Morrison Street, Portland, OR, 97205-2626, US

(73) Assignee: Quanta Computer Inc., Tao-Yuan Hsien (TW)

(21) Appl. No.: 10/282,743

(22) Filed: Oct. 28, 2002

(51) Int. Cl. H05K 7/20

(52) U.S. Cl. 361/695; 165/80.3; 454/184

(57) ABSTRACT

A heat dissipating device includes a thermal conductive housing with ventilating holes and a plurality of thermal conductive surrounding partition members disposed in the housing to confine a plurality of receiving spaces which are fluidly communicated with one another via central through holes. A motor shaft of a fan motor extends through the through holes. A plurality of impellers are respectively mounted to the motor shaft and are displaced from one another so as to be received in the receiving spaces, respectively, such that a stream of cooling air can be brought into a respective one of the receiving spaces to take heat away from the surrounding partition members.

### BACKGROUND OF THE INVENTION

1. Field of the Invention

This invention relates to a heat dissipating device, more particularly to a heat dissipating device adapted to dissipate heat generated by an electronic device.

2. Description of the Related Art

Referring to FIGS. 1 and 2, a conventional heat dissipating device 4 is shown to include a heat sink 41 and a fan 42. The heat sink 41 includes a base 411 which is mounted on a top surface of an electronic component 2 in a computer casing 3, and a plurality of dissipating fins 412 which project from the base 411. The fan 42 includes a fan housing 421 which confines inlet and outlet ports 424,425, and a motor (not shown) which is mounted between the inlet and outlet ports 424,425 and which is provided with a motor shaft 422 for rotating a plurality of fan blades 423. The fan housing 421 is mounted on the heat sink 41. Thus, by rotation of the fan blades 423, a stream of cooling air can be brought into the fan housing 421 to take heat away from the dissipating fins 412 for dissipating heat generated by the electronic component 2. However, the streams of air generated by the fan blades 423 flow in different directions and interfere with each other so as to reduce the efficiency of heat dissipation.

Another arrangement of the conventional heat dissipating device is shown in FIG. 3. The bases 411 of two heat sinks 41 are mounted on electronic components 2 in a computer casing 3 with inlet and outlet holes 311,312 formed in opposite sides thereof. A fan 42 is secured in a vicinity of the inlet holes 311, and defines an inlet port (not shown) and an outlet port 425 respectively proximate and distal to the inlet holes 311 such that by rotation of the blades of the fan 42, a cooling air stream flow can be brought into the casing 3 to take heat away from the dissipating fins 412 of the heat sink 41 via the outlet holes 312. Since the fan 42 is distant from the heat sink 41, the efficiency of heat dissipation is reduced.

### SUMMARY OF THE INVENTION

The object of the present invention is to provide a heat dissipating device which can achieve a highly efficient heat dissipation.

According to this invention, the heat dissipating device includes a thermal conductive housing which is adapted to be in thermal contact with an electronic device, and which includes top and bottom walls spaced apart from each other in a longitudinal direction, and an outer surrounding wall interposed between the top and bottom walls. The outer surrounding wall has inner and outer peripheral wall surfaces which surround an axis in the longitudinal direction and which are opposite to each other in radial directions. The inner peripheral wall surface cooperates with the top and bottom walls to confine an accommodation chamber. A plurality of thermal conductive surrounding partition members are disposed in the accommodation chamber, are spaced apart from each of the top and bottom walls, and are displaced from each other in the longitudinal direction so as to partition the accommodation chamber into a plurality of receiving spaces. Each surrounding partition member extends from the inner peripheral wall surface radially and inwardly, and terminates at an inner peripheral edge which confines a through hole. The outer surrounding wall of the housing has a plurality of ventilating holes which are formed therethrough and which are fluidly communicated with the receiving spaces of the accommodation chamber, respectively. A fan motor is provided with a motor shaft extending through the through holes and rotatable about the axis. A plurality of impellers are mounted for rotation with the motor shaft, and are displaced from one another along the axis. Each impeller includes a plurality of fan blades which are angularly displaced from one another about the axis and which are disposed to extend radially into a respective one of the receiving spaces.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is an exploded perspective view of a conventional heat dissipating device;

FIG. 2 is a schematic view showing the conventional heat dissipating device when mounted on an electronic component of a computer;

FIG. 3 is a schematic view showing another arrangement of the conventional heat dissipating device when mounted in a computer casing;

FIG. 4 is a fragmentary exploded perspective view of a preferred embodiment of a heat dissipating device according to this invention;

FIG. 5 is a fragmentary exploded perspective view of the preferred embodiment;

FIG. 6 is a fragmentary partly sectional view of the preferred embodiment;

FIG. 7 is a partly sectional view of the preferred embodiment, taken along lines A-A of FIG. 6; and

FIG. 8 is a perspective view showing the preferred embodiment when mounted in a casing of a computer.

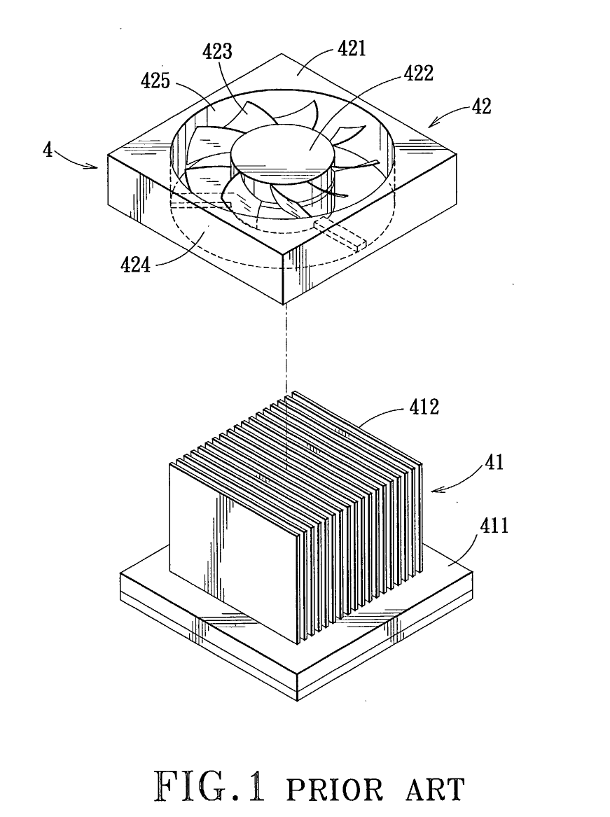

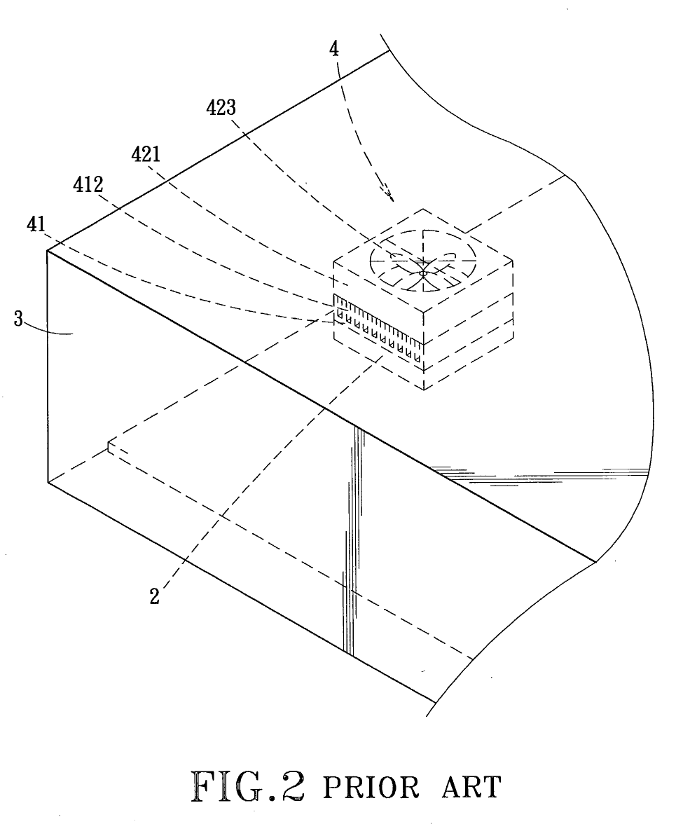

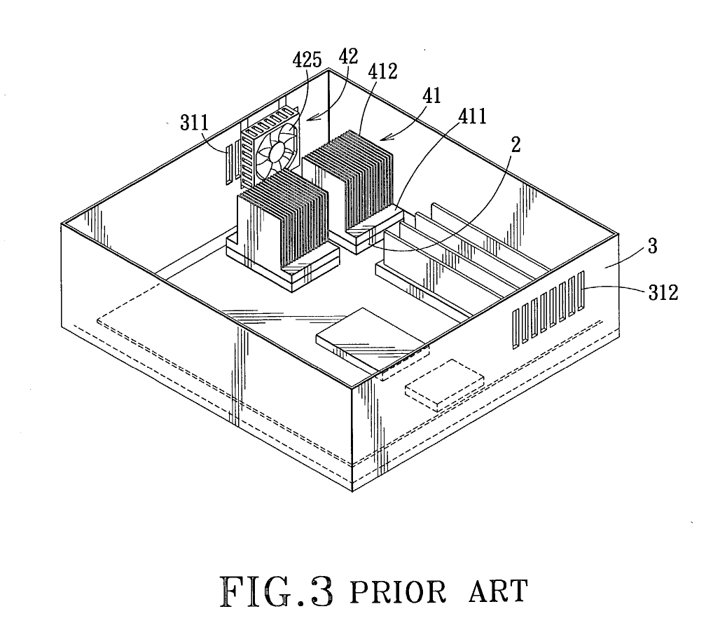

### DETAILED DESCRIPTION OF THE PREFERRED EMBODIMENT

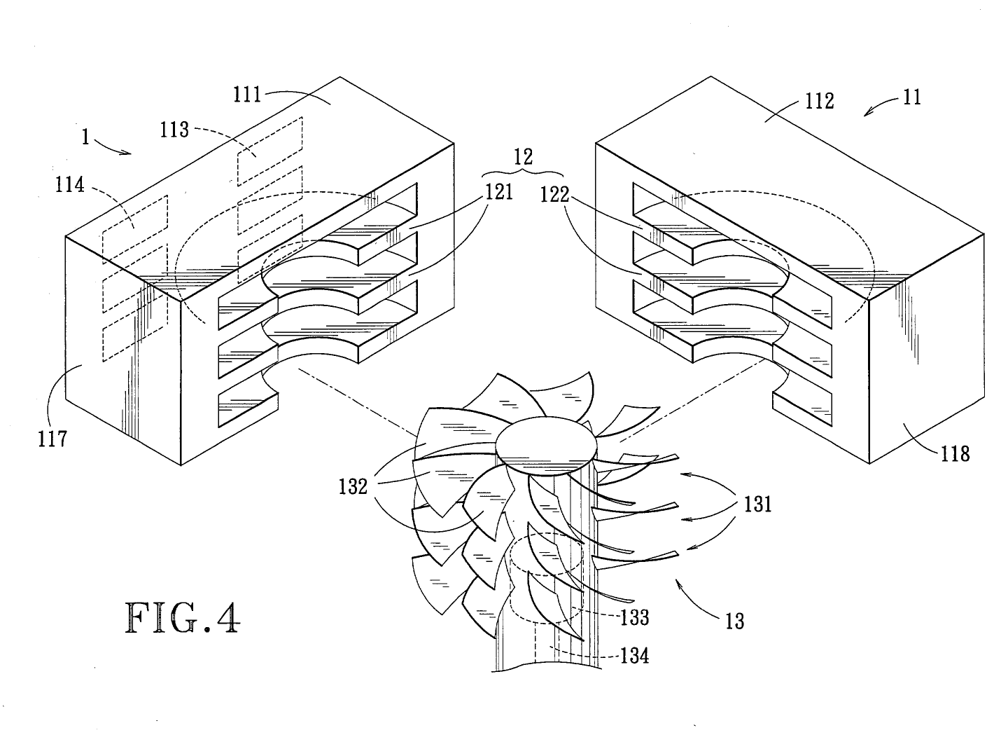

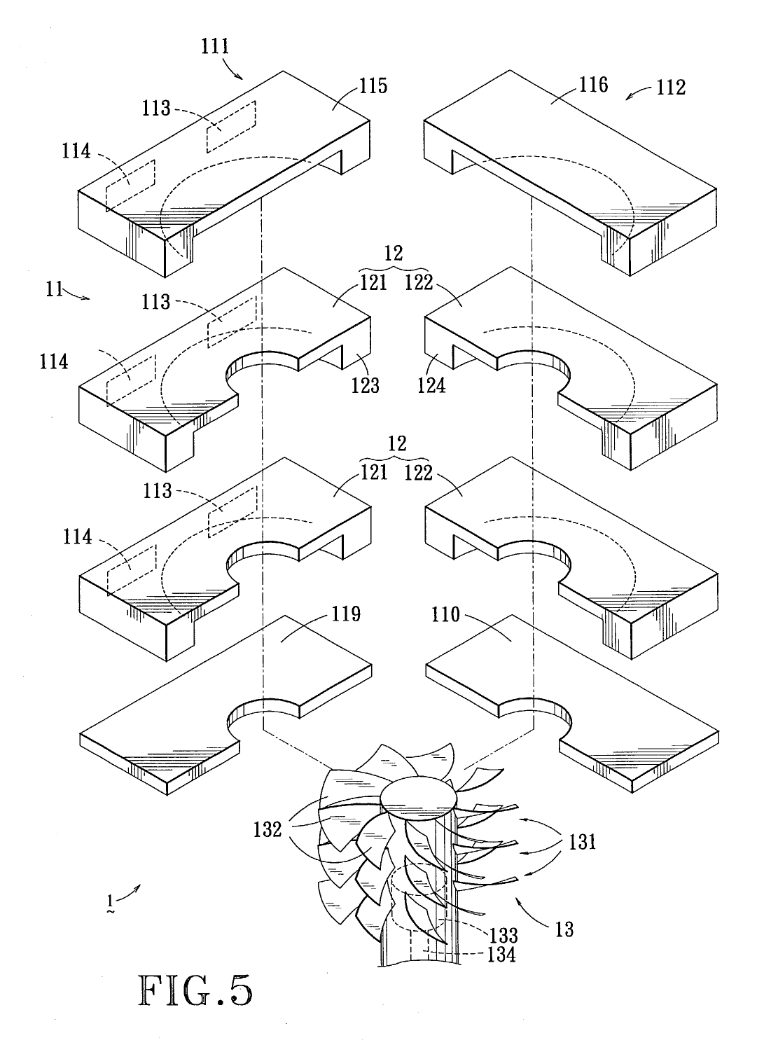

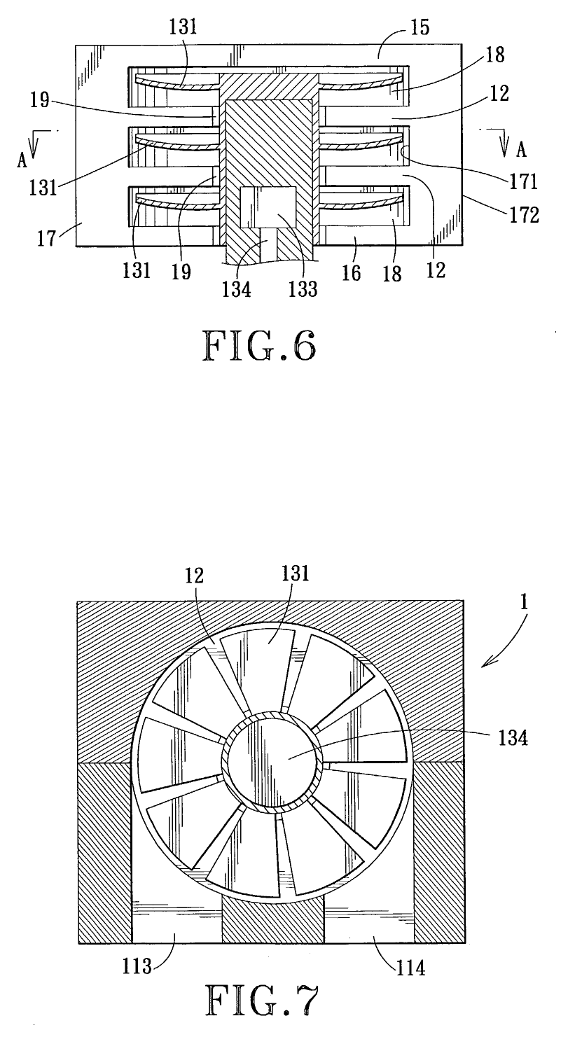

Referring to FIGS. 4, 5 and 6, the preferred embodiment of the heat dissipating device 1 according to the present invention is shown to comprise a thermal conductive housing 11, a plurality of plate-shaped thermal conductive surrounding partition members 12, and a fan 13.

The thermal conductive housing 11 includes left and right housing halves 111,112. The left and right housing halves 111,112 respectively have left and right top wall portions 115,116 which confront and engage each other to form a top wall 15 of the housing 11, left and right bottom wall portions 119,110 which are respectively spaced apart from the left and right top wall portions 115,116 in a longitudinal direction and which confront and engage each other to form a bottom wall 16 of the housing 11, and left and right outer surrounding wall portions 117,118 which are respectively interposed between the top and bottom walls 15,16 and which confront and engage each other to form an outer surrounding wall 17 of the housing 11. The outer surrounding wall 17 has inner and outer peripheral wall surfaces 171,172 which surround an axis in the longitudinal direction and which are opposite to each other in radial directions. The inner peripheral wall surface 171 cooperates with the top and bottom walls 15,16 to confine an accommodation chamber.

The thermal conductive surrounding partition members 12 are disposed in the accommodation chamber, are spaced apart from each of the top and bottom walls 15,16, and are displaced from each other in the longitudinal direction so as to partition the accommodation chamber into a plurality of receiving spaces 18. Each of the surrounding partition members 12 includes left and right half partition portions 121,122 which respectively extend from the inner peripheral wall surface 171 radially and inwardly, and which terminate at inner peripheral edges 123,124. The inner peripheral edges 123,124 confront and engage each other, and confine a through hole 19 surrounding the axis. In this embodiment, the left half partition portions 121 are formed integrally with the left housing half 111, and the right half partition portions 122 are formed integrally with the right housing half 112. The housing 11 and the surrounding partition members 12 are made of aluminum alloy.

Moreover, the left outer surrounding wall portion 117 has a plurality of pairs of ventilating holes 113, 114 which are formed therethrough and which are fluidly communicated with the receiving spaces 18, respectively. The ventilating holes 113,114 of each pair include an inlet port 113, and an outlet port 114 which is displaced angularly from the inlet port 113 about the axis.

The fan 13 includes a fan motor 133 which is provided with a motor shaft 134 which is disposed to extend through the through holes 19 and which is rotatable about the axis, and a plurality of impellers 131 which are respectively mounted for rotation with the motor shaft 134 and which are displaced from one another along the axis. Each of the impellers 131 includes a plurality of fan blades 132 which are angularly displaced from one another about the axis and which are disposed to extend radially into the respective receiving space 18 so as to impel air therein. Preferably, the inlet ports 113 are aligned with one another in the longitudinal direction, and the outlet ports 114 are aligned with one another in the longitudinal direction.

Thus, a stream of cooling air can be brought through the respective inlet port 113 communicated with the respective receiving space 18 to take heat away from a respective one of the surrounding partition members 12. The hot air in the respective receiving space 18 can be fanned out of the respective receiving space 18 through the respective outlet port 114 so as to maximize effect of heat dissipation.

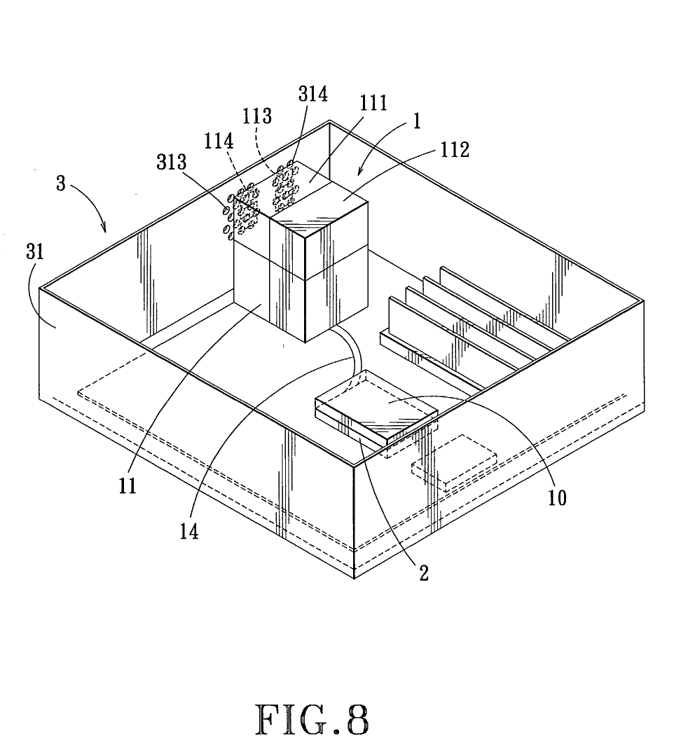

As shown in FIGS. 4, 6 and 8, when the heat dissipating device 1 is applied to a casing 31 of a computer 3 which has a plurality of through holes 314,313, the inlet and outlet ports 113,114 are disposed to register with the through holes 314,313, respectively. Then, a heat sink 10 is mounted on a top surface of an electronic component 2, such as a CPU, and a heat conductive member 14, such as a heat pipe, is used to interconnect the heat sink 10 and the housing 11 so as to conduct heat from the electronic component 2 to the housing 11.

As illustrated, by virtue of the impellers 131 which are rotated synchronously in the same direction and which are received respectively in the receiving spaces 18, the flow of cooling air can be supplied into the respective receiving spaces 18 via the respective through hole 314 and the respective inlet port 113 without interference, and can take heat away from the respective surrounding partition members 12 via the respective outlet port 114 and the respective through hole 313. Thus, highly efficient heat dissipation can be achieved.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

I claim:

1. A heat dissipating device adapted to dissipate heat generated by an electronic device, comprising:
a thermal conductive housing adapted to be in thermal contact with the electronic device, and including top and bottom walls which are spaced apart from each other in a longitudinal direction, and an outer surrounding wall interposed between said top and bottom walls and having inner and outer peripheral wall surfaces which surround an axis in the longitudinal direction and which are opposite to each other in radial directions, said inner peripheral wall surface cooperating with said top and bottom walls to confine an accommodation chamber;
a plurality of thermal conductive surrounding partition members which are disposed in said accommodation chamber, which are spaced apart from each of said top and bottom walls, and which are displaced from each other in the longitudinal direction so as to partition said accommodation chamber into a plurality of receiving spaces, each of said surrounding partition members extending from said inner peripheral wall surface radially and inwardly and terminating at an inner peripheral edge which surrounds the axis and which confines a through hole, said outer surrounding wall of said housing having a plurality of ventilating holes which are formed therethrough and which are fluidly communicated with said receiving spaces of said accommodation chamber, respectively;
a fan motor provided with a motor shaft which is disposed to extend through said through holes and which is rotatable about the axis; and
a plurality of impellers respectively mounted for rotation with said motor shaft, and displaced from one another along the axis, each of said impellers including a plurality of fan blades which are angularly displaced from one another about the axis and which are disposed to extend radially into a respective one of said receiving spaces so as to impel air therein, thereby bringing through a respective one of said ventilating holes communicated with the respective one of said receiving spaces a stream of cooling air which will take heat away from a respective one of said surrounding partition members so as to maximize effect of heat dissipation.

2. The heat dissipating device of claim 1, wherein said ventilating holes communicated with the respective one of said receiving spaces include at least one inlet port for bringing the stream of cooling air into the respective one of said receiving spaces, and at least one outlet port which is displaced angularly from said inlet port about the axis so as to permit hot air to be fanned out of the respective one of said receiving spaces.

3. The heat dissipating device of claim 2, wherein said inlet ports are aligned with one another in the longitudinal direction, and said outlet ports are aligned with one another in the longitudinal direction.

4. The heat dissipating device of claim 1, wherein said housing includes right and left housing halves respectively including right and left top wall portions which confront and engage each other to form said top wall, right and left bottom wall portions which confront and engage each other to form said bottom wall, and right and left outer surrounding wall portions which confront and engage each other to form said outer surrounding wall.

5. The heat dissipating device of claim 4, wherein each of said surrounding partition members includes right and left half partition portions which confront and engage each other, said right half partition portions of said surrounding partition members being formed integrally with said right housing half, said left half partition portions of said surrounding partition members being formed integrally with said left housing half.

6. The heat dissipating device of claim 1, further comprising a heat sink which is adapted to be mounted on the electronic device, and a heat conductive member which interconnects said heat sink and said housing so as to conduct heat from the electronic device to said housing.
